(19) United States
(12) Patent Application Publication
(10) Pub. No.: US 2015/0382489 A1
(43) Pub. Date: Dec. 31, 2015

(54) MAGNET ARRANGEMENT FOR MOUNTS, CLOSURES AND FASTENERS

(71) Applicant: Joseph Alan Sorensen, Bend, OR (US)

(72) Inventor: Joseph Alan Sorensen, Bend, OR (US)

(21) Appl. No.: 14/736,691

(22) Filed: Jun. 11, 2015

Related U.S. Application Data
(60) Provisional application No. 61/998,377, filed on Jun. 27, 2014.

(51) Int. Cl. H05K 5/02; F16B 2/08; A45F 5/02; F16B 1/00; F16M 13/02

(52) U.S. Cl. CPC H05K 5/0204; F16B 1/00; F16M 13/022; A45F 5/02; F16B 2/08; A45F 5/021; H05K 5/0234; F16B 2001/0035

(57) ABSTRACT

A mounting arrangement includes a first portion having a spherical or frusto-conical surface made of a magnetically attractable material; and a second portion configured to matingly engage with the first portion. The second portion includes a mounting body portion housing a magnet and a ring, made of an elastomeric material, disposed on top of the magnet. The elastomeric ring defines a seat for accepting the first portion. The mounting body portion includes an outer shoulder. When the first and second portions are brought into proximity to one another, the shoulder provides a bearing surface for the first portion such that the first portion, magnetically attracted to the second portion, slides on the shoulder into the seat.

### INCORPORATION BY REFERENCE

The present application claims benefit of U.S. Provisional Patent Application No. 61/998,377, filed Jun. 27, 2014, the entire contents of which are incorporated by reference herein as if fully set forth.

### FIELD OF THE INVENTION

The present invention relates to a magnet arrangement used for mounting an object to another object or for closures and fasteners.

### BACKGROUND

It has been known to use magnets for removably mounting an object to another object, e.g. refrigerator magnets, magnetic hooks, removable decals, etc. Specifically, magnetic ball and socket connectors have been used to provide quick, simple one-handed mounting of an object to another object. The magnetic ball and socket arrangements additionally provide a relative range of motion between the mounted objects. One such possible use of this type of magnetic ball and socket arrangement is for mounting a mobile phone to a car dashboard. An example of such a system is currently sold under the name “Steelie”.

However, such connections are often heavy and bulky. These types of magnets are often made by sintering and then plated with a thin layer of nickel and as a result they are brittle. As in the case of the “Steelie” product the magnet directly contacts the steel ball, which creates the possibility for breakage of the brittle magnets and creates a hard knock against the device. Further, this system requires mounting a powerful magnet directly to the phone to be mounted in a stand. It has been discovered that mounting a powerful magnet to the phone disables compass features of phones and can erase the magnetic strips of credit/debit cards when the phone is placed nearby.

Magnet arrangements have also been used as closures or fasteners for various items, e.g. purses, wallets, bags, belts, etc. However, such closures have been known to be easily undone or difficult to align to close.

Users often prop up a mobile phone to make the screen viewable without having to hold the phone. For this purpose, cases for mobile phones or tablet devices often include stands built into them. However, such cases are specific to the phone or tablet and are often quite bulky. Some designs utilize a separate piece which can be used with different phones or tables, but are not intended to be left on the phone or tablet and must be removed when not in use.

Therefore, it is desirable to have a mobile phone mount without requiring a magnet to be directly attached to a phone or tablet device. It is also desirable to have a magnetic closure/fastener system that is easy to align and is secure. It is further desirable to have a magnetic mount and stand which attaches to any mobile device or stand providing a discreet profile when not in use.

The above objects are achieved by the features of the appended independent claims.

### SUMMARY

According to a first embodiment, the present disclosure is directed to a mounting arrangement including a first portion having a spherical or frusto-conical surface made of a magnetically attractable material; and a second portion configured to matingly engage with the first portion. The second portion includes a mounting body portion housing a magnet and a ring, made of an elastomeric material, disposed on top of the magnet. The elastomeric ring defines a seat for accepting the first portion. The mounting body portion includes an outer shoulder, wherein when the first and second portions are brought into proximity to one another, the shoulder provides a bearing surface for the first portion such that the first portion, magnetically attracted to the second portion, slides on the shoulder into the seat.

In a second embodiment, the present disclosure is directed to a fastening arrangement including a first connection portion having a spherical or frusto-conical surface made of a magnetically attractable material; and a second connection portion configured to matingly engage with the first connection portion. The second connection portion houses a magnet and a ring, made of an elastomeric material, disposed on top of the magnet. The elastomeric ring defines a seat for accepting the first connection portion. The second connection portion comprises an outer shoulder, wherein when the first and second connection portions are brought into proximity to one another, the shoulder provides a bearing surface for the first connection portion such that the first connection portion, magnetically attracted to the second connection portion, slides on the shoulder into the seat.

The following detailed description of the preferred embodiment of the present invention will be better understood when read in conjunction with the appended drawings. For the purpose of illustrating the invention, there are shown in the drawings embodiments, which are presently preferred. It is understood, however, that the invention is not limited to the precise arrangements and instrumentalities shown. In the drawings:

### BRIEF DESCRIPTION OF THE DRAWINGS

FIGS. 1 and 2 are perspective views of a first mounting portion of a mounting arrangement configured as a stand;

FIG. 3 is a perspective view of the mounting arrangement in use with a mobile device;

FIG. 4 is a perspective view of the mounting body of the mounting arrangement;

FIG. 5 is a cross-section, taken along a centerline, of the mounting arrangement according to the present invention prior to engagement of the first and second portions;

FIG. 6 is a view similar to that of FIG. 5 where the first and second portions are substantially engaged;

FIG. 7 is a view similar to that of FIG. 6 where the first and second portions are engaged;

FIG. 8 is top plan view of an alternate embodiment of the invention configured as a fastening arrangement;

FIG. 9 is a partial sectional view of the arrangement of FIG. 8 prior to engagement of first and second fastening portions; and

FIG. 10 is a view similar to that of FIG. 9 where the first and second fastening portions are substantially engaged.

Certain terminology is used in the following description for convenience only and is not limiting. The words “right,” “left,” “top,” and “bottom” designate directions in the drawings to which reference is made. The words “a” and “one,” as used in the claims and in the corresponding portions of the specification, are defined as including one or more of the referenced item unless specifically stated otherwise. This terminology includes the words above specifically mentioned, derivatives thereof, and words of similar import. The phrase “at least one” followed by a list of two or more items, such as “A, B, or C,” means any individual one of A, B or C as well as any combination thereof.

### DETAILED DESCRIPTION OF THE PREFERRED EMBODIMENTS

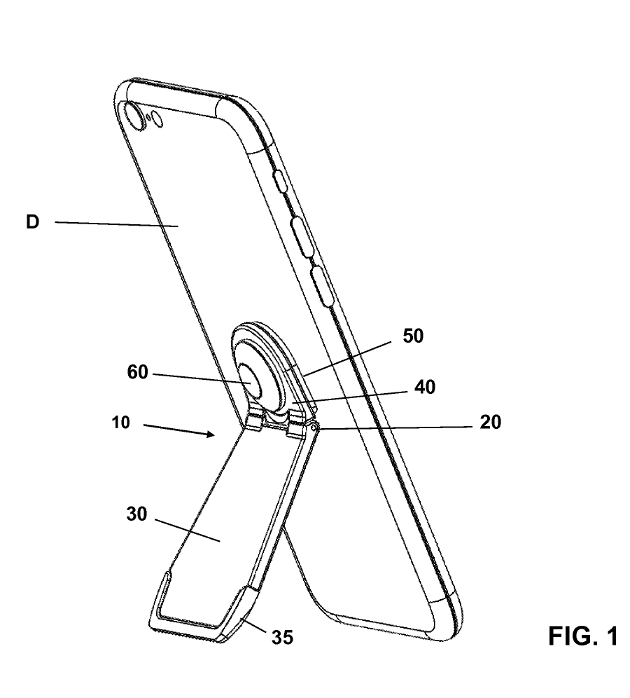

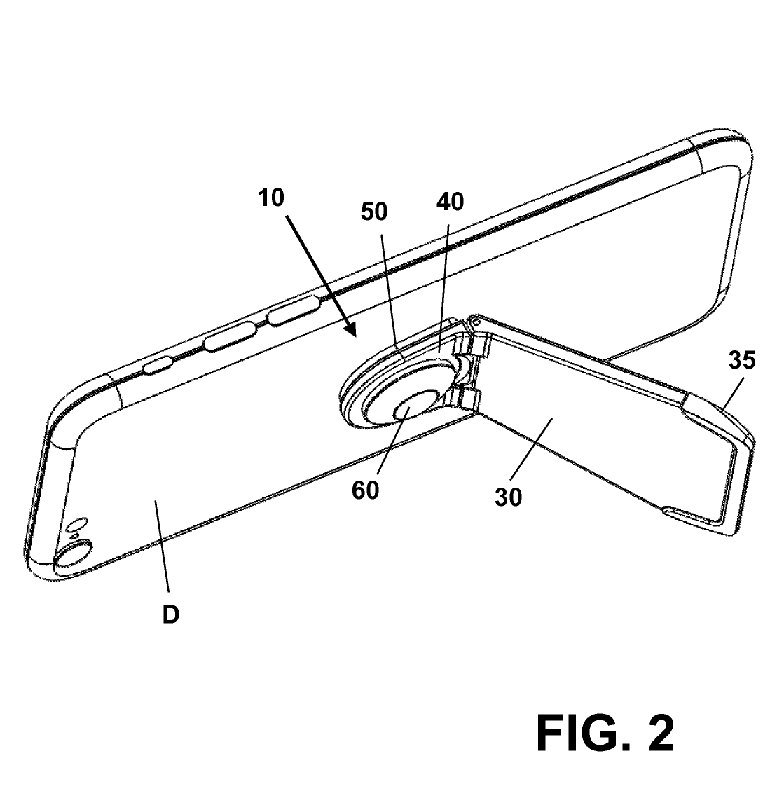

FIG. 1 depicts a device D having a stand 10 attached thereto. Stand 10 comprises a base portion 40, a leg portion 30 and a hinge 20 connecting the base to the leg. The stand 10 is attached to the device by an adhesive layer 50 of the base portion 40 of the stand 10. The stand 10 has a first mounting portion 60 that is magnetically attractable however is not magnetic. FIG. 1 depicts the device being propped in a portrait orientation. FIG. 2 depicts the device being propped in a landscape orientation this is possible owing to a chamfer 35 in the leg 30.

It should be understood that the figures show the first mounting portion 60 incorporated into the stand 10, however the first mounting portion 60 may be also used without the stand 10.

To attach the stand 10 to a device, a user simply stands the device vertically on a flat surface with the mounting portion 60 centered in the back. This aligns the center of the mounting portion 60 to the phone's center of gravity. A release layer or backing is removed from the adhesive layer 50 and the mounting portion 60 is pressed onto the back of the device or a case therefor, to which the stand is to be attached.

To use as a stand the leg 30 is pulled outwardly away from the device or case and rotated about hinge 20. Since the hinge 20 is proximate a center of gravity of the device, the device is able to rest stably on its edge and the leg 30 of the stand 10 is configured to be used in portrait or landscape orientation owing to a chamfer 35 on the leg 30 of the stand 10. When not in use, the leg 30 is simply folded back toward the device. The stand 10, along with the mounting portion 60, can also be incorporated into a case for the device instead of being a separate part.

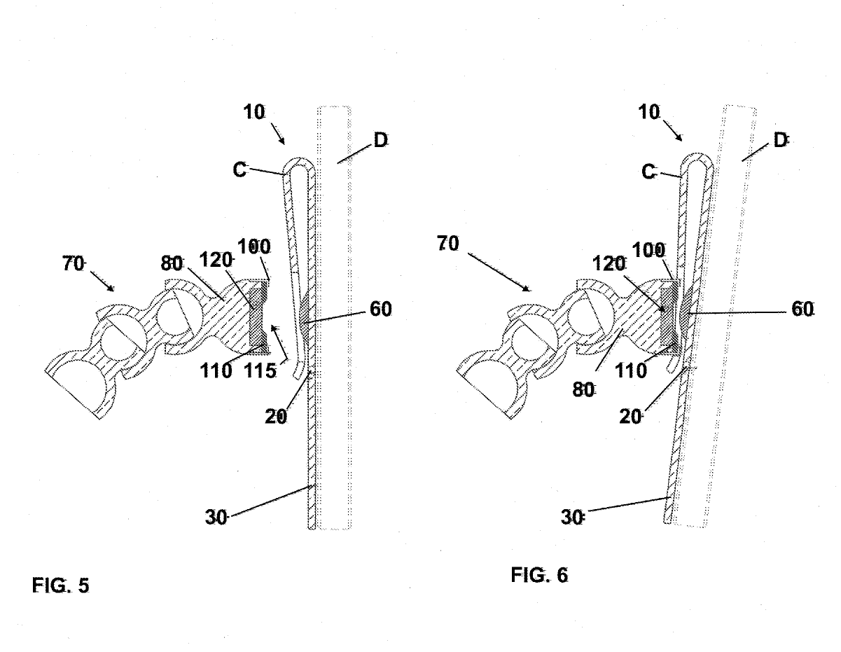

As can be seen in FIG. 5, the stand also comprises a portion configured as a clip C. The clip C can be used as a belt clip in order to be secured on the person of the user. Alternatively, the clip can be used to keep currency and credit cards in the form of a money clip when not mounted.

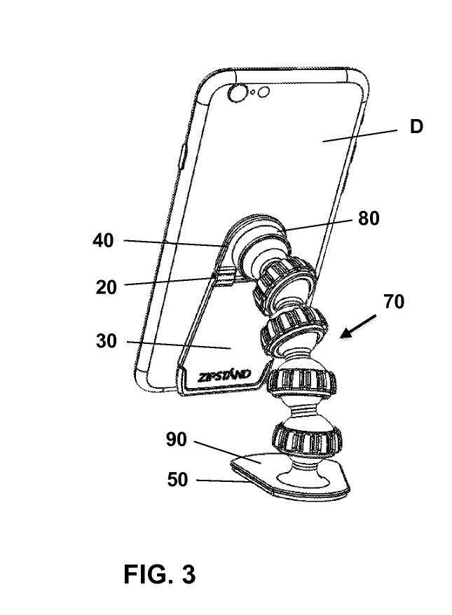

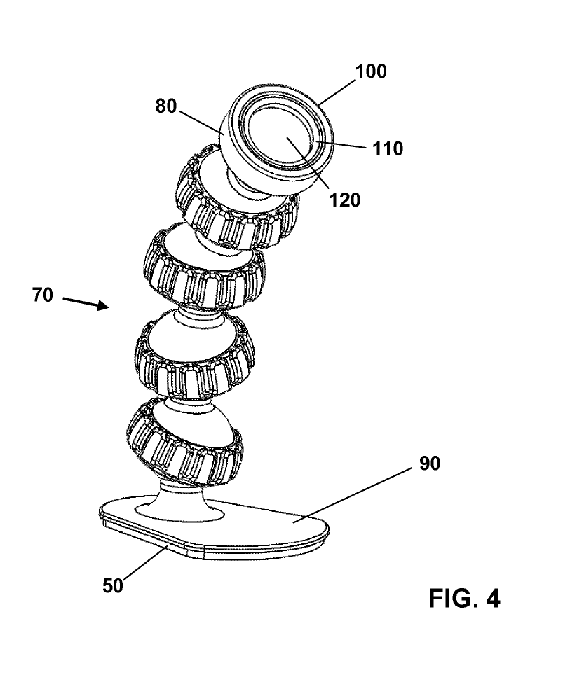

It should be noted that the device described can be a mobile telephone, a tablet computer, a portable television, a navigation system (GPS), a portable computer screen, and the like. It should also be noted that the stand 10 can be connected either directly to the device D or to a case housing the device. FIG. 3 depicts the stand and first mounting portion 60 in use with a second mounting portion 70. The stand 10, along with mounting portion 60, is kept in place by the magnetic mounting portion 80 which will be discussed in further detail below.

The second portion 70 includes a mounting body portion 80, which houses a magnet 120 and a ring 110, made of an elastomeric material, disposed on top of the magnet 120. It should be noted that the magnet can be any Ferro-magnetic material, preferably, the magnet is a neodymium or other rare earth magnet. It should also be considered that the magnet is an electromagnet. The elastomeric ring 110 defines a seat 115 for receiving the first portion 60. The mounting body portion 80 also includes an outer shoulder 100, which acts as a bearing when the first and second portions 60, 70 are brought into proximity to one another. The shoulder 100 provides a bearing surface for the first portion 60 such that the first portion 60, magnetically attracted to the second portion 70, slides on the shoulder 100 into the seat 115.

The shoulder 100 can either be integral with the body portion 80 or can be a separate ring that snaps into place by way of a snap-fit or similar connection. The shoulder 100 can be made of a material that is smooth and non-magnetic, for example: a hardwood, a hard plastic such as: nylon, ABS or high-density polyethylene (HDPE) for example, aluminum and any material having a Shore Scale D durometer of at least 75. Shoulder 100 provides a guide to allow the first portion 60 to find the magnetic center. Further, it prevents the first portion from attaching to the periphery of the mounting body portion 80 before centering. The shoulder also provides a fulcrum for when the device is to be removed or detached from the mounting body portion 80.

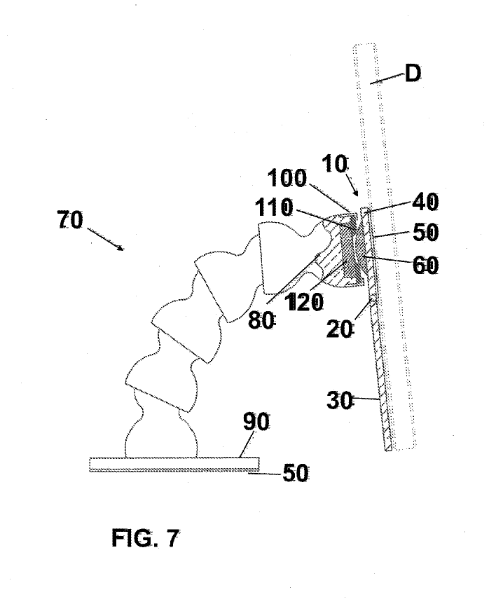

The elastomeric ring 110 provides a grip to prevent any unwanted rotation of the device. Further, the ring 110 cushions the receiving of the first portion into the seat 115, thereby preventing any contact that could result in potential damage to the magnet as well as the device. Moreover, owing to the elastomeric ring, the insertion or acceptance of the first portion 60 into the seat 115 is cushioned and therefore quieted. As shown in FIG. 7, the magnet 120 and the magnetically attractable portion 60 do not actually touch.

The mounting arrangement is akin to a ball and socket connection. As such, the first portion can rotate 360° in the socket of the second portion 70. Even though the first portion is rotatable within the second portion 70 the connection provides a strong magnetic attraction between the magnet 120 of the second portion 70 and the spherical surface of the first portion 60.

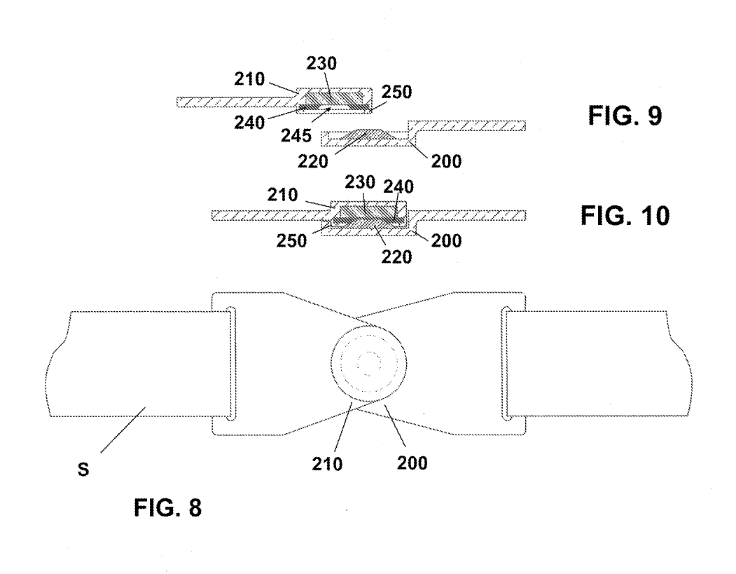

FIG. 8 depicts a second embodiment of the present invention. FIG. 8 shows a top view of a fastening arrangement between two fastening bodies 200, 210. AS shown in FIGS. 9 and 10, first connection portion 200 has a spherical or frusto-conical surface 220 made-up of a magnetically attractable material. The second connection portion 210 is configured to matingly engage with the first connection portion.

The second connection portion 210 houses a magnet 230 and a ring 240, which is made of elastomeric material, and is disposed on top of the magnet 230. The elastomeric ring 240 defines a seat 245, which is configured to accept the first connection portion 200, specifically the spherical or frusto-conical surface 220 thereof. The second connection portion 210 also includes an outer shoulder 250 and when the first and second connection portions 200, 210 are brought into proximity to one another, the shoulder acts as a bearing surface for the first connection portion 200. The first connection portion 200, which is magnetically attracted to the second connection portion 210 slides on the shoulder 250 and into the seat 245. Effectively, the shoulder 250 assists the magnetically attractable portion 200 to be centered in the seat 245. The shoulder 250 can either be integral with the second connection portion 210 or can be a separate piece. The shoulder 250 also acts as a fulcrum when the first connection portion 200 is to be disengaged from the second connection portion 210. The shoulder 250 can be made of a non-magnetic material such as: for example: a hardwood, a hard plastic such as: nylon, ABS or high-density polyethylene (HDPE) for example, aluminum and any material having a Shore Scale D durometer of at least 75.

The fastening arrangement described above can be used as a closure. Owing to its ease of self centering and strong closure, the fastening arrangement can be used as a closure for several different situations, for example as a closure for: a purse, a wallet, an article of luggage, a box, an article of jewelry or an article of clothing.

The first and second connecting portions 200, 210 can be attached to straps S as shown in FIG. 8. Straps S can be used with: bicycle helmet strap closures, backpacks, belts, tie down straps, roof racks, or anything that bungee cords are currently used for.

It is understood, therefore, that this invention is not limited to the particular embodiments disclosed, but is intended to cover all modifications which are within the spirit and scope of the invention as defined by the appended claims; the above description; and/or shown in the attached drawings.

What is claimed is:

1. A mounting arrangement comprising a first portion (60) having a spherical or frusto-conical surface made of a magnetically attractable material; and a second portion (70) configured to matingly engage with the first portion (60), the second portion (70) comprising a mounting body portion (80) housing a magnet (120) and a ring (110), made of an elastomeric material, disposed on top of the magnet (120), the elastomeric ring (110) defining a seat (115) for accepting the first portion (60), the mounting body portion (80) comprising an outer shoulder (100), wherein when the first and second portions (60, 70) are brought into proximity to one another, the shoulder (100) providing a bearing surface for the first portion (60) such that the first portion (60), magnetically attracted to the second portion (70), slides on the shoulder (100) into the seat (115).

2. The mounting arrangement of claim 1, wherein the shoulder (100) is integral with the mounting body portion (80).

3. The mounting arrangement of claim 1, wherein the shoulder (100) acts as a fulcrum when the first portion (60) is to be disengaged from the second portion (70).

4. The mounting arrangement of claim 1, wherein the shoulder (100) is comprised of a smooth non-magnetic material selected from the group consisting of: a hardwood, a hard plastic, nylon, ABS, high-density polyethylene (HDPE), aluminum and any material having a Shore Scale D durometer of at least 75.

5. The mounting arrangement of claim 1, wherein the second portion (70) comprises a base portion (90) configured to be attached to a surface.

6. The mounting arrangement of claim 1, wherein the first portion (60), when seated in the second portion (70) is rotatable up to 360°.

7. The mounting arrangement of claim 1, wherein the first portion (60) is a component of a stand (10) for a device (D).

8. The mounting arrangement of claim 7, wherein the stand (10) comprises a leg (30) and a hinge (20), the leg (30) being articulable away from the device (D) to provide a support for the device (D).

9. The mounting arrangement of claim 8, wherein the stand (10) further comprises a base portion (40), which is attachable to the device (D), or a case housing the device, via an adhesive layer (50).

10. The mounting arrangement of claim 8, wherein the stand (10) is integral with a case configured to house the device (D).

11. The mounting arrangement of claim 9, wherein the stand (10) further comprises a clip (C) associated with the base portion (40).

12. The mounting arrangement of claim 1, wherein the first portion (60) and the magnet (120) do not touch when the first portion (60) is engaged with the second portion (70).

13. A fastening arrangement comprising a first connection portion (200) having a spherical or frusto-conical surface (220) made of a magnetically attractable material;
and a second connection portion (210) configured to matingly engage with the first connection portion (200), the second connection portion (210) houses a magnet (230) and a ring (240), made of an elastomeric material, disposed on top of the magnet (230), the elastomeric ring (240) defining a seat (245) for accepting the first connection portion (200), the second connection portion (210) comprises an outer shoulder (250), wherein the when the first and second connection portions (200, 210) are brought into proximity to one another, the shoulder (250) provides a bearing surface for the first connection portion (200) such that the first connection portion (200), magnetically attracted to the second connection portion (210), slides on the shoulder (250) into the seat (245).

14. The fastening arrangement of claim 13, wherein the shoulder (250) is integral with the second connection portion (210).

15. The fastening arrangement of claim 13, wherein the shoulder (250) acts as a fulcrum when the first connection portion (200) is to be disengaged from the second connection portion (210).

16. The fastening arrangement of claim 13, wherein the shoulder (250) is comprised of a smooth non-magnetic material selected from the group consisting of: a hardwood, a hard plastic, nylon, ABS, high-density polyethylene (HDPE), aluminum and any material having a Shore Scale D durometer of at least 75.

17. The fastening arrangement of claim 13, wherein the first and second connecting portions are configured for use as a closure for any one of the following: a purse, a wallet, an article of luggage, a box, an article of jewelry or an article of clothing.

18. The fastening arrangement of claim 13, wherein the first and second connecting portions (200, 210) are each attached to straps (S).

19. The fastening arrangement of claim 18, wherein the fastening arrangement is configured for use as a strap connector for any one of the following: a bicycle helmet, a backpack, a belt, tie-downs, roof racks or couplers.

20. The fastening arrangement of claim 13, wherein the spherical or frusto-conical surface (220) and the magnet (230) do not touch when the first portion (200) is engaged with the second portion (210).
